(19) United States
(12) Patent Application Publication
(10) Pub. No.: US 2007/0007531 A1
(43) Pub. Date: Jan. 11, 2007

(54) Semiconductor device and manufacturing method thereof

(76) Inventor: Kwak Sung Ho, Seoul (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/483,305

(22) Filed: Jul. 7, 2006

(30) Foreign Application Priority Data
Jul. 8, 2005 (KR) 10-2005-0061708

(51) Int. Cl. H01L 29/76

(52) U.S. Cl. 257/66

(57) ABSTRACT

A semiconductor device and a manufacturing method thereof are provided. The semiconductor device includes a semiconductor substrate, a first gate insulating layer, a second gate insulating layer, a first gate electrode, and a second gate electrode. The semiconductor substrate is divided into a first region and a second region. The first gate insulating layer is formed on the first region. The second gate insulating layer is formed on the second region and formed thinner than the first gate insulating layer. The first gate electrode is formed on the first gate insulating layer. The second gate electrode is formed on the second gate insulating layer and formed thicker than the first gate electrode

### RELATED APPLICATION

This application claims the benefit, under 35 U.S.C. §119(e), of Korean Patent Application Number 10-2005-0061708 filed Jul. 8, 2005, which is incorporated herein by reference in its entirety.

### FIELD OF INVENTION

The present invention relates to a semiconductor device and a manufacturing method of the semiconductor device.

### BACKGROUND OF INVENTION

Generally, a metal-oxide semiconductor (MOS) device includes channels that are passages for current flowing immediately beneath an oxide layer of a semiconductor substrate. The channels are formed by a bias applied between a metal layer and the semiconductor substrate. Additionally, the channels are controlled by bias values.

Precipitated by recent developments in semiconductor manufacturing, gate oxide layers are becoming thinner, and dual gate oxide layers are being used.

Specifically, dual gate oxide layers are being formed with different thicknesses in order to form transistors having different operating voltage characteristics on the same substrate.

When the thickness of the gate oxide layer is made relatively thin, depletion of polysilicon used as gate electrodes and penetration of boron or other dopants into the silicon occur.

It should be noted that the polysilicon depletion and boron penetration are mutually contradictory phenomena.

When the dopant concentration of the gate electrode polysilicon is reduced near the gate oxide layer, capacitance values between inversion and accumulation of a transistor become different. That is, the capacitance value during transistor inversion decreases, inducing deterioration of the transistor's characteristics.

On the other hand, when the dopant concentration of the gate electrode polysilicon is increased near the gate oxide layer, dopants for the gate electrode spread to a silicon interface of the transistor. In this way, the transistor's characteristics deteriorate. This phenomenon becomes severe as the thickness of the gate oxide layer becomes increasingly thinner.

### BRIEF SUMMARY OF THE INVENTION

An object of the present invention is to provide a semiconductor device and a manufacturing method thereof that can increase the concentration of poly around a gate oxide layer at a region where the gate oxide thickness of the gate oxide layer is high.

Another object of the present invention is to provide a semiconductor device and a manufacturing method thereof that can increase poly depletion characteristics and reduce resistance.

Another object of the present invention is to provide a semiconductor device and a manufacturing method thereof capable of blocking dopant penetration at a region of a gate oxide layer having a low gate oxide thickness.

To achieve these objects and other advantages and in accordance with the purpose of the invention, as embodied and broadly described herein, there is provided a semiconductor device including: a semiconductor substrate having a first region and a second region; a first gate insulating layer formed on the first region; a second gate insulating layer formed on the second region and formed thinner than the first gate insulating layer; a first gate electrode formed on the first gate insulating layer; and a second gate electrode formed on the second gate insulating layer and formed thicker than the second gate electrode.

In another aspect of the present invention, there is provided a manufacturing method of a semiconductor device, including: forming a first gate insulating layer on a first region of a semiconductor substrate; forming a second gate insulating layer that is thinner than the first gate insulating layer on a second region of the semiconductor substrate; forming a first gate electrode on the first gate insulating layer; forming a second gate electrode on the second gate insulating layer by forming an insulating layer on the first region of the semiconductor substrate including the first gate electrode, forming a polysilicon layer on an entire surface of the semiconductor substrate, and selectively etching the polysilicon layer; removing the insulating layer on the first region after forming the second gate electrode; and doping the first gate electrode and the second gate electrode with dopant ions.

### BRIEF DESCRIPTION OF DRAWINGS

FIG. 1 is a sectional view of a semiconductor device according to an embodiment of the present invention.

FIGS. 2A through 2G are sectional views showing a manufacturing method of a semiconductor device according to an embodiment of the present invention.

### DETAILED DESCRIPTION OF THE INVENTION

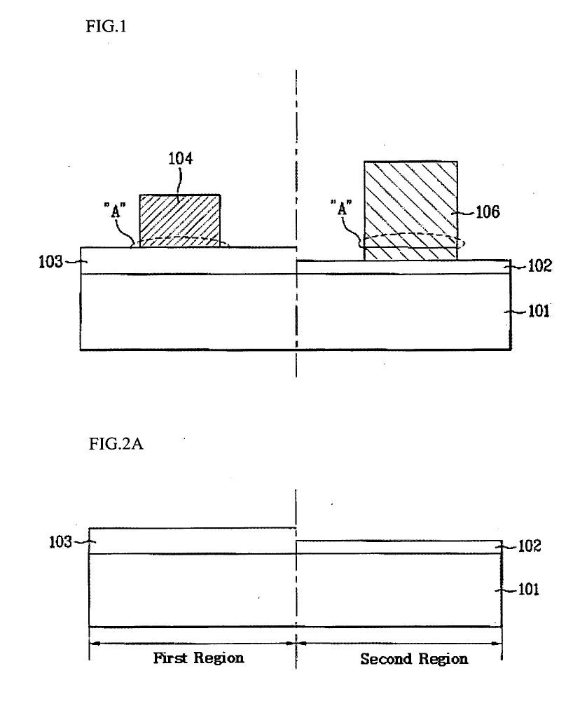

FIG. 1 is a sectional view of a semiconductor device according to an embodiment of the present invention.

Referring to FIG. 1, a semiconductor device according to an embodiment of the present invention can incorporate a semiconductor substrate 101 having a first region and a second region. The first region can be used to form transistors having one type of operating voltage characteristics and the second region can be used to form transistors having another type of voltage characteristics. The device can incorporate a first gate insulating layer 103 and a second gate insulating layer 102 formed respectively on the first region and the second region of the semiconductor substrate 101 where the first gate insulating layer 103 and the second gate insulating layer 102 can have different thicknesses. The device can also incorporate a first gate electrode 104 and a second gate electrode 106 formed respectively on the first and second regions where the first gate electrode 104 and the second gate electrode 106 can have different thicknesses.

In one embodiment, the first gate insulating layer 103 formed on the first region can be formed thicker than the second gate insulating layer 102 formed on the second region.

In a specific embodiment, the second gate insulating layer 102 can be 30-50% of the thickness of the first gate insulating layer 103.

In an embodiment example, the second gate insulating layer 102 may be 21 Å, and the first gate insulating layer 103 may be 52 Å.

In one embodiment, the second gate electrode 106 formed on the second region can be formed thicker than the first gate electrode 104 formed on the first region.

In a specific embodiment, the second gate electrode 106 can be formed to be 110-130% of the thickness of the first gate electrode 104.

In an embodiment example, the second gate electrode 106 may be 1800 Å, and the first gate electrode may be 1500 Å.

In an embodiment, the concentration of dopant in the first gate insulating layer 103 can be higher than the concentration of dopant in the second gate insulating layer 102.

In a specific embodiment, an ion implantation target point “A” can be set at different points for the first gate electrode 104 and the second gate electrode 106 such that the concentration of dopant on the first gate insulating layer 103 is higher than that of dopant on the second gate insulating layer 102.

Accordingly, embodiments of the present invention can increase the poly (dopant) concentration near a gate oxide at a high gate oxide thickness region to improve the poly depletion characteristics and reduce resistance.

The gate electrode can be thickly formed at the region where the gate oxide thickness is low in order to prevent dopant penetration.

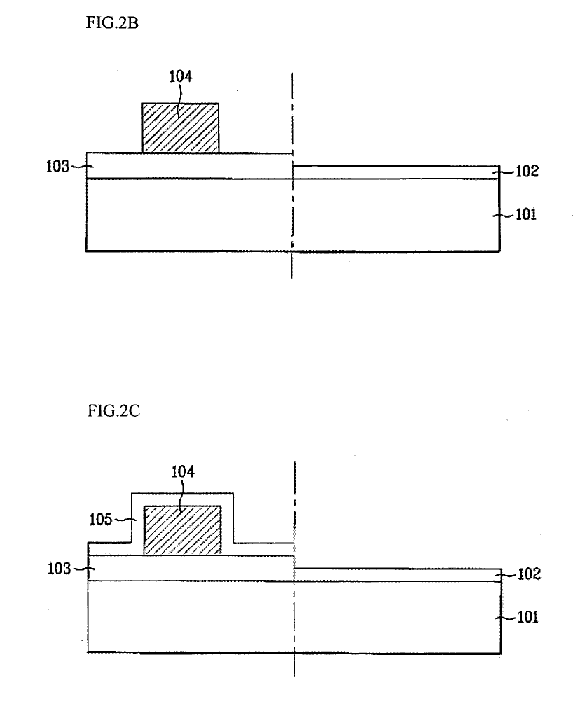

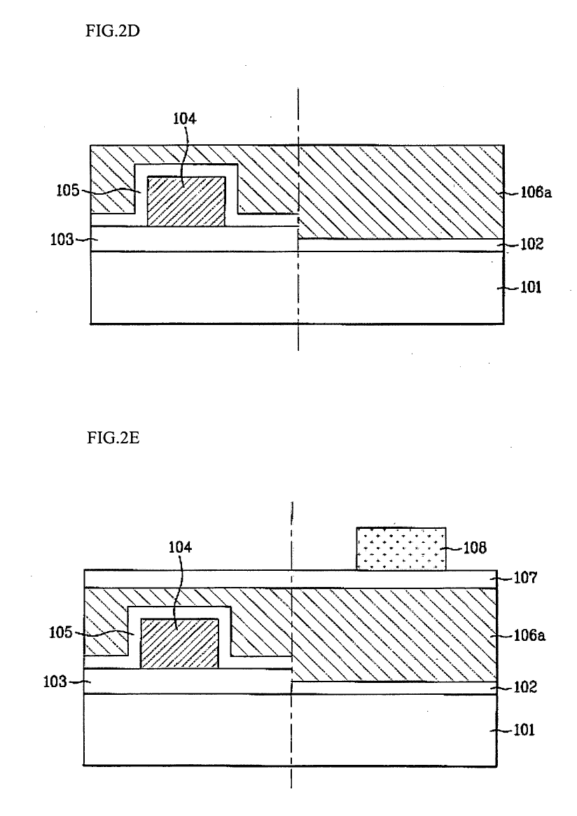

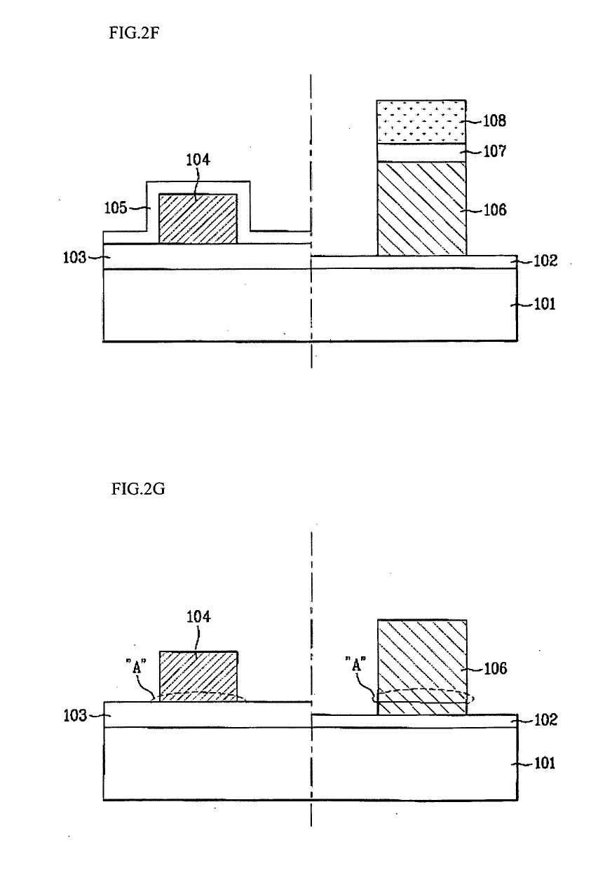

Below, a manufacturing method of a semiconductor device according to an embodiment the present invention will be described with reference to the FIGS. 2A through 2G.

Referring to FIG. 2A, a first gate insulating layer 103 and a second gate insulating layer 102 with mutually different thicknesses can be formed on a semiconductor substrate 101. The first gate insulating layer 103 can be formed in a first region of the semiconductor substrate 101 and the second gate insulating layer 102 can be formed in a second region of the semiconductor substrate 101.

In a specific embodiment, the second gate insulating layer 102 can have a thickness of approximately 30-50% of the first gate insulating layer 103.

In an embodiment example, the second gate insulating layer 102 may be 21 Å, and the first gate insulating layer 103 may be 52 Å.

In one embodiment, the forming method of the first and second insulating layers 102 and 103 having different respective thicknesses can be as follows.

A first oxidation process can be performed to form a predetermined original insulating layer (not shown) on the entire surface of semiconductor substrate 101 intended for a predetermined gate insulating layer.

Then, the portion of the original insulating layer on the second region can be etched and removed to form a stepped insulating layer between the first and second regions.

In a further embodiment, a second thermal oxidation can be performed to form a secondary insulating layer on the entire surface of the semiconductor substrate 101 including where the original insulating layer is etched away on the second region. Accordingly, the first gate insulating layer 103 can be made of the original insulating layer and the secondary insulating layer on the first region, and the second gate insulating layer 102 can be made of the secondary insulating layer on the second region.

The first gate insulating layer 103 and the second gate insulating layer 102 can be formed of an oxide layer or a nitride layer.

In another embodiment, the forming method of the first and second gate insulating layers 103 and 102 can be described as follows.

First, a first oxidation process can be performed on the entire surface of the semiconductor substrate 101 to form an original insulating layer (not shown) for a predetermined gate insulating layer.

Then, oxide ions can be implanted into the original insulating layer on the first region.

Subsequently, a second oxidation process can be performed to form the first gate insulating layer 103 higher on the first region than the remaining surface of the semiconductor substrate.

Accordingly, the original insulating layer forms the second gate insulating layer 102, and the original insulating layer that undergoes oxide ion implantation and a second thermal process forms the first gate insulating layer 103.

Referring to FIG. 2B, a first polysilicon layer can be deposited on the entire surface of the semiconductor substrate 101. The first polysilicon layer can be selectively removed through photo and etching processes, whereupon a first gate electrode can be formed on a certain portion of the first region.

Referring to FIG. 2C, an insulating layer 105 can be formed on the entire surface of the semiconductor device 101 including the first gate electrode 104. A selective patterning using photo and etching processes can be performed so that the insulating layer 105 only remains on the first region. In a specific embodiment, the insulating layer 105 of the first region can be a nitride layer.

Referring to FIG. 2D, a second polysilicon layer 106a can be deposited on the entire surface of the semiconductor substrate including the remaining insulating layer 105.

Referring to FIG. 2E, in a further embodiment, an anti-reflection layer 107 can be formed on the second polysilicon layer 106a. A photoresist 108 can be applied to the anti-reflection layer 107 and a gate region defined through patterning with light exposing and developing processes.

The anti-reflection layer 107 can be used to ensure that the pattern for the photoresist is formed properly.

Referring to FIG. 2F, the anti-reflection layer 107 and the second polysilicon layer 106a can be selectively removed using the patterned photoresist 108 as a mask to form a second gate electrode 106 on a predetermined portion of the second region.

In one embodiment, the second gate electrode 106 can be formed to be thicker than the first gate electrode 104.

In a specific embodiment, the second gate electrode 106 can be formed to be 110-130% the thickness of the first gate electrode 104.

In an embodiment example, the second gate electrode 106 may be formed to be 1800 Å, and the first gate electrode 104 may be formed to be 1500 Å.

In embodiments, when the second polysilicon layer 106a for forming the second gate electrode 106 is etched, the first gate electrode 104 can be protected by the insulating layer 105 formed on the first region.

Also, when the second polysilicon layer 106a is etched, an etching selection ratio for the insulating layer 105 can be used. In a further embodiment, a fluorine (F)-type gas can be used for etching the second polysilicon layer 106a.

Then, the photoresist 108, the anti-reflection layer 107, and the insulating layer 105 can be removed.

Referring to FIG. 2G, ions can be implanted into the first and second gate electrodes. In one embodiment, the dopant ion can be boron.

In a specific embodiment, in order to raise the dopant, an implanted ion implantation target point (A) can be different at the first gate electrode 104 formed on the first gate insulating layer 103 and the second gate electrode 106 formed on the second gate insulating layer 102.

That is, in the stage of doping the dopant ions, in the case of the first region, an ion implantation target point can be disposed above the boundary between the first gate insulating layer 103 and the first gate electrode 104. The dopant concentration at the first gate insulating layer 103 is made higher then that of the second gate insulating layer 102.

For example, in the doping process of the dopant ions, the ion implantation target point rises 10-100 Å from the boundary between the first gate insulating layer 103 and the first gate electrode 104, so that the dopant concentration at the first gate insulating layer 103 is higher than that of the second gate insulating layer 102.

Additionally, the ion implantation target point is disposed at the bottom of the second gate electrode 106 on the second region, so that the dopant concentration at the second gate insulating layer 102 is lower than that at the first gate insulating layer 103.

The present invention can produce the following effects.

First, embodiment of the present invention can raise the concentration of dopant at the thicker first gate insulating layer 103 having low dopant penetration, so that polysilicon depletion can be reduced, which increases the characteristics of the semiconductor device. Also, the thickness of the first gate electrode 104 can be reduced to produce the effect of lowering the gate resistance.

On the other hand, the dopant concentration at the thin second gate insulating layer 102 with a high dopant penetration is reduced, so that the effects of dopant penetration can be reduced.

In another embodiment of the present invention, a gate insulating layer having another thickness can be formed, a thin gate insulating layer can be formed on a thick gate insulating layer, and conversely, a thick gate electrode can be formed on a thin gate insulating layer.

It will be apparent to those skilled in the art that various modifications and variations can be made in the present invention. Thus, it is intended that the present invention covers the modifications and variations of this invention provided they come within the scope of the appended claims and their equivalents.

I claim:

1. A semiconductor device comprising:
a semiconductor substrate;
a first gate insulating layer formed on a first region of the semiconductor substrate;
a second gate insulating layer formed on a second region of the semiconductor substrate, wherein the second gate insulating layer is thinner than the first gate insulating layer;
a first gate electrode formed on the first gate insulating layer; and
a second gate electrode formed on the second gate insulating layer, wherein the second gate electrode is thicker than the first gate electrode.

2. The semiconductor device according to claim 1, wherein the second gate insulating layer has a thickness 30-50% of a thickness of the first gate insulating layer.

3. The semiconductor device according to claim 1, wherein the first gate insulating layer is a nitride layer having a different etching selectivity from the first gate electrode, wherein the first gate electrode is a polysilicon layer.

4. The semiconductor device according to claim 1, wherein the second gate electrode has a thickness 110-130% of a thickness of the first gate electrode.

5. The semiconductor device according to claim 1, wherein the first gate insulating layer on the first region and the first gate electrode form a boundary therebetween, wherein an ion implantation target of 10-100 Å in height is disposed above the boundary, and wherein the first gate insulating layer has a dopant concentration that is higher than a dopant concentration of the second gate insulating layer.

6. The semiconductor device according to claim 1, wherein an ion implantation target is disposed at a bottom of the second gate electrode on the second region, and the second gate insulating layer has a dopant concentration that is lower than a dopant concentration of the first gate insulating layer.

7. A manufacturing method of a semiconductor device, comprising:
forming a first gate insulating layer on a first region of a semiconductor substrate
forming a second gate insulating layer on a second region of the semiconductor substrate, wherein the second gate insulating layer is formed to be thinner than the first gate insulating layer;
forming a first gate electrode on the first gate insulating layer;
forming a second gate electrode on the second gate insulating layer by forming an insulating layer on the first region of the semiconductor substrate including the first gate electrode, forming a polysilicon layer on an entire surface of the semiconductor substrate, and selectively etching the polysilicon layer;
removing the insulating layer on the first region after forming the second gate electrode; and
doping the first gate electrode and the second gate electrode with dopant ions.

8. The manufacturing method according to claim 7, wherein forming the first gate insulating layer and forming the second gate insulating layer comprises:
forming an original insulating layer on an entire surface of the semiconductor substrate;
etching the original insulating layer formed on the second region; and
forming a secondary insulating layer through thermal oxidation on the entire surface of the semiconductor substrate including the original insulating layer.

9. The manufacturing method according to claim 7, wherein the second gate insulating layer has a thickness of 30-50% of a thickness of the first gate insulating layer.

10. The manufacturing method according to claim 7, wherein the insulating layer formed on the first region is a nitride layer having etching selectivity different from that of the polysilicon layer.

11. The manufacturing method according to claim 7, wherein the second gate electrode is formed thicker than the first gate electrode.

12. The manufacturing method according to claim 11, wherein the second gate electrode has a thickness of 110-130% of a thickness of the first gate electrode.

13. The manufacturing method according to claim 7, wherein selectively etching the polysilicon layer comprises using a fluorine-based gas.

14. The manufacturing method according to claim 7, wherein doping the first and second gate electrodes with dopant ions uses boron as the dopant ions.

15. The manufacturing method according to claim 7, wherein doping the first and second gate electrodes comprises:
disposing an ion implantation target point above a boundary between the first gate insulating layer and the first gate electrode on the first region, wherein the ion implantation target point is used for making a dopant concentration at the first gate insulating layer higher than a dopant concentration at the second gate insulating layer.

16. The manufacturing method according to claim 7, wherein doping the first and second electrodes comprises:
disposing an ion implantation target point with a height of 10-100 Å from a boundary between the first gate insulating layer and the first gate electrode on the first region, wherein the ion implantation target point is used for making a dopant concentration at the first gate insulating layer higher than a dopant concentration at the second gate insulating layer.

17. The manufacturing method according to claim 7, wherein doping the first and second electrodes comprises:
disposing an ion implantation target point at a bottom of the second gate electrode on the second region, wherein the ion implantation target point is used for making a dopant concentration at the second gate insulating layer lower than a dopant concentration at the first gate insulating layer.

18. The manufacturing method according to claim 7, further comprising forming an anti-reflective coating on the polysilicon layer.
